(19) United States
(12) Patent Application Publication
(10) Pub. No.: US 2025/0273549 A1
(43) Pub. Date: Aug. 28, 2025

(54) MULTI-CHIP PACKAGE, METHOD FOR REDUCING PEAK CURRENT AND SEMICONDUCTOR DEVICE

(71) Applicant: MACRONIX INTERNATIONAL CO., LTD., Hsinchu (TW)

(72) Inventors: Shih-Chou JUAN, Taoyuan City (TW); Shun-Li CHENG, Zhubei City (TW); Hung-Yi CHIANG, Hsinchu County (TW); Shao-Yu WANG, New Taipei City (TW)

(21) Appl. No.: 18/585,137

(22) Filed: Feb. 23, 2024

(51) Int. Cl. H01L 23/498; H01L 25/065

(52) U.S. Cl. CPC H01L 23/49816; H01L 25/0655

(57) ABSTRACT

The application discloses a multi-chip packaging structure, a method for reducing peak current and a semiconductor device. A plurality of chips are packed on a substrate. A plurality of packaging balls are embedded on the substrate, connected to a plurality of power sources. A plurality of connection nodes are packed on the substrate to connect the packaging balls to the chips. The power sources include a plurality of first power sources and second power sources. The packaging balls include a plurality of first packaging balls and second packaging balls, with the first packaging balls connected to the first power sources and the second packaging balls connected to the second power sources. The first packaging balls are connected to a part of the chips through the connection nodes.

### TECHNICAL FIELD

The disclosure relates in general to a multi-chip package, a method for reducing peak current and a semiconductor device.

### BACKGROUND

Multi-Chip Package (MCP) is a packaging technology that integrates multiple integrated circuit chips into a single package structure. This packaging technique is commonly used to integrate multiple functional components into a smaller packaging structure to save space, enhance performance, or meet other specific requirements.

MCP may pack multiple chips with different functions or purposes, such as: (1) Memory and processor combination: Integrating processor and memory chips in the same package to improve data access speed and reduce latency. (2) Communication: Combining wireless communication chips and other relevant control or signal processors in one package to achieve a more compact communication circuit or module. (3) Sensor and controller combination: Integrating sensors (such as accelerometers, gyroscopes) and corresponding controllers in one package to provide a full-featured sensing solution. (4) Chips manufactured using different processes: Combining multiple chips manufactured using different processes to achieve different performance and power consumption requirements within the same package.

In general, Multi-Chip Package is commonly used to achieve goals such as high integration, space savings, performance improvement, power consumption reduction, or meeting other specific needs. This packaging technology is prevalent in many applications, including mobile devices, embedded systems, communication circuits, or modules.

Due to the integration of multiple chips in a single package, special attention needs to be paid to the potential peak current situations in Multi-Chip Package.

In Multi-Chip Package, if all chips are connected to the same power supply positive pole (Vcc) and power supply negative pole (Vss), this type of connection may lead to certain issues. For instance, in this extreme connection scenario, concerns arise about excessively high peak currents causing operational issues in the system. Excessive peak currents may result in system instability or abnormal operation. This is because if the peak current is too high, the internal voltage drop within the chips can be severe, potentially leading to system crashes and abnormal states.

Therefore, addressing how to reduce peak currents to ensure stable system operation is a crucial issue that needs to be resolved.

### SUMMARY

According to one embodiment, provided is a multi-chip packaging structure comprising: a substrate having a plurality of chips packed on the substrate; a plurality of packaging balls embedded on the substrate, connected to a plurality of power sources; and a plurality of connection nodes packed on the substrate to connect the packaging balls to the chips, wherein the power sources include a plurality of first power sources and a plurality of second power sources; the packaging balls include a plurality of first packaging balls and a plurality of second packaging balls, with the first packaging balls connected to the first power sources and the second packaging balls connected to the second power sources; and the first packaging balls are connected to a part of the chips through the connection nodes.

According to another embodiment, provided is a method for reducing a peak current of a semiconductor packaging structure, the method comprising: packing a plurality of packaging balls in the semiconductor packaging structure, where the packaging balls are embedded on a substrate and are connected to a plurality of power sources; packing a plurality of connection nodes on the substrate to connect the packaging balls to a plurality of chips on the substrate; wherein: the power sources include a plurality of first power sources and a plurality of second power sources; the packaging balls include a plurality of first packaging balls and a plurality of second packaging balls, with the first packaging balls connected to the first power sources and the second packaging balls connected to the second power sources; and the first packaging balls are connected to a part of the chips through the connection nodes.

According to an alternative embodiment, provided is a semiconductor device comprising: a plurality of chips; a substrate having the chips packed on the substrate; a plurality of packaging balls embedded on the substrate, connected to a plurality of power sources; and a plurality of connection nodes packed on the substrate to connect the packaging balls to the chips, wherein: the power sources include a plurality of first power sources and a plurality of second power sources; the packaging balls include a plurality of first packaging balls and a plurality of second packaging balls, with the first packaging balls connected to the first power sources and the second packaging balls connected to the second power sources; and the first packaging balls are connected to a part of the chips through the connection nodes.

### BRIEF DESCRIPTION OF THE DRAWINGS

FIG. 1 illustrates a top view schematic diagram of a Multi-Chip Package (MCP) structure according to the first embodiment of the present invention.

FIG. 2 shows a vertical schematic diagram of the MCP structure according to the first embodiment of the present invention.

FIG. 3 illustrates a top view schematic diagram of a Multi-Chip Package (MCP) structure according to the second embodiment of the present invention.

FIG. 4 shows a method for reducing the peak current of a semiconductor package structure according to the third embodiment of the present invention.

In the following detailed description, for purposes of explanation, numerous specific details are set forth in order to provide a thorough understanding of the disclosed embodiments. It will be apparent, however, that one or more embodiments may be practiced without these specific details.

In other instances, well-known structures and devices are schematically shown in order to simplify the drawing.

### DESCRIPTION OF THE EMBODIMENTS

Technical terms of the disclosure are based on general definition in the technical field of the disclosure. If the disclosure describes or explains one or some terms, definition of the terms is based on the description or explanation of the disclosure. Each of the disclosed embodiments has one or more technical features. In possible implementation, one skilled person in the art would selectively implement part or all technical features of any embodiment of the disclosure or selectively combine part or all technical features of the embodiments of the disclosure.

### First Embodiment

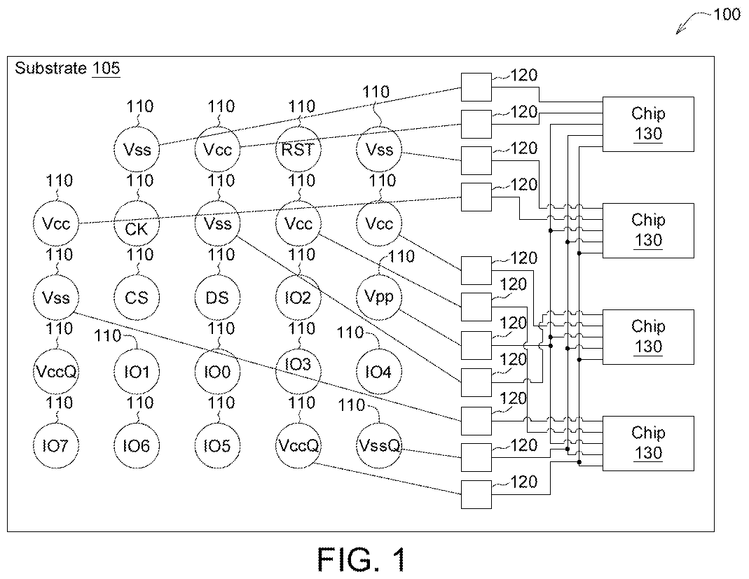

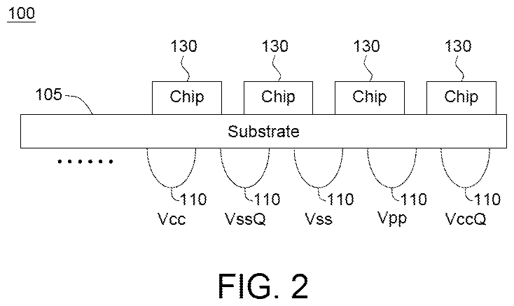

FIG. 1 illustrates a top view schematic diagram of a Multi-Chip Package (MCP) structure according to the first embodiment of the present invention. FIG. 2 shows a vertical schematic diagram of the MCP structure according to the first embodiment of the present invention.

As shown in FIG. 1, the MCP structure 100 according to the first embodiment of the present invention includes: a substrate 105, multiple packaging balls 110, and multiple connection nodes 120. In addition, multiple chips 130 are packed on the substrate 105. These chips 130 include, but are not limited to, NAND flash memory chips or communication chips.

The connection nodes 120 are packed on the substrate 105 to connect the packaging balls 110 to the chips 130.

The packaging balls 110 are embedded on the substrate 105. These packaging balls 110 can be connected to various power sources (reference voltages), including but not limited to, Vcc, Vss, VccQ, Vpp, VssQ, where Vcc provides operating voltage (e.g., normal operating voltage), and Vss provides ground voltage. VccQ, Vpp, VssQ provide the required voltage during the startup process of the chips 130, and once the chips 130 are operational after startup, VccQ, Vpp, VssQ generally do not provide voltage. For ease of understanding, Vcc and Vss can be referred to as the first power source, while VccQ, Vpp, VssQ can be referred to as the second power source.

In other words, if the packaging balls 110 connected to the power sources Vcc and Vss provide excessively high peak currents to the chips 130, it may lead to unstable or abnormal system operation, system crashes, and other issues.

Therefore, in the first embodiment of the present invention, to avoid the problem of potentially excessive peak currents and reduce the load on the power sources Vcc and Vss, the peak current flowing through the packaging balls 110 connected to Vcc and Vss is reduced. For clarity, the packaging balls 110 connected to the power sources Vcc and Vss are referred to as Vcc packaging balls 110 and Vss packaging balls 110 (or the packaging balls 110 connected to the power sources Vcc and Vss are referred to as the first packaging balls). Similarly, the packaging balls 110 connected to the power sources VccQ, Vpp, VssQ are referred to as VccQ packaging balls 110, Vpp packaging balls 110, VssQ packaging balls 110 (or the packaging balls 110 connected to the power sources VccQ, Vpp, VssQ are referred to as the second packaging balls).

In detail, a smaller number of chips 130 are connected to the same Vcc packaging ball 110 to avoid having all chips 130 connected to the same Vcc packaging ball 110. Similarly, a smaller number of chips 130 are connected to the same Vss packaging ball 110 to avoid having all chips 130 connected to the same Vss packaging ball 110.

Refer again to FIG. 1. As shown in FIG. 1, only one chip 130 is connected to a single Vcc packaging ball 110, and similarly, only one chip 130 is connected to a single Vss packaging ball 110. For example, the topmost chip 130 in FIG. 1 is connected to the second left Vcc packaging ball 110 in the first horizontal row via connection nodes 120, and the topmost chip 130 in FIG. 1 is connected to the leftmost Vss packaging ball 110 in the first horizontal row via connection nodes 120.

A single VccQ packaging ball 110, a single Vpp packaging ball 110 or a single VssQ packaging ball 110 can be connected to one or more chips 130. For example, the single Vpp packaging ball 110 in FIG. 1 is connected to all chips 130. The rest can be inferred accordingly. Because during normal operation of the system, large currents are usually not needed from the power sources VccQ, VssQ, and Vpp, there is generally no concern about excessively high peak currents.

Example: In the first embodiment of the present invention, the difference with prior art is explained by taking an example. In the prior art, assuming each chip requires 1 A of current, and if a single Vcc packaging ball is connected to 3 chips, then the Vcc power source (not shown) has to provide 3 A of current, which may exceed the upper limit of the peak current, leading to unstable or even system collapse. In contrast, in the first embodiment of the present invention, assuming each chip requires 1 A of current, and if a single Vcc packaging ball is connected to 1 chip, then each Vcc power source (not shown) has to provide 1 A of current. In this case, the probability of exceeding the upper limit of the peak current is significantly reduced, greatly reducing the possibility of system instability or system collapse.

### Second Embodiment

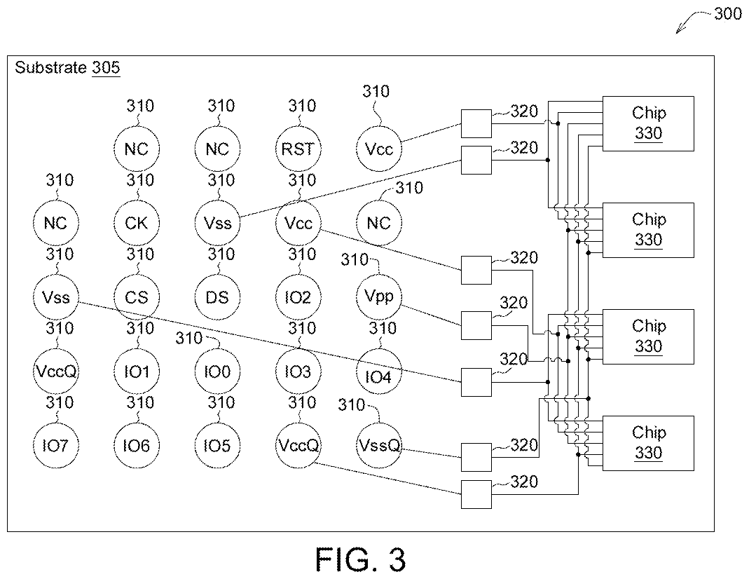

FIG. 3 illustrates a top view schematic diagram of a Multi-Chip Package (MCP) structure according to the second embodiment of the present invention.

As shown in FIG. 3, the MCP structure 300 according to the second embodiment of the present invention includes: a substrate 305, multiple packaging balls 310, and multiple connection nodes 320. In addition, multiple chips 330 can be packed on the substrate 305. These chips 330 include, but are not limited to, NAND flash memory chips or communication chips.

Similarly, in the second embodiment of the present invention, to avoid the problem of potentially excessive peak currents and reduce the load on the power sources Vcc and Vss, it is avoided that all chips 330 are connected to the same Vcc packaging ball 310, and all chips 330 are avoided from being connected to the same Vss packaging ball 310.

In the second embodiment of the present invention, 2 chips 330 are connected to a single Vcc packaging ball 310, and 2 chips 330 are connected to a single Vss packaging ball 310. For example, the topmost chip 330 and the second top chip 330 in FIG. 3 are connected to the Vcc packaging ball 310 in the first horizontal row via connection nodes 320, and the topmost chip 330 and the second top chip 330 in FIG. 3 are connected to the Vss packaging ball 310 in the second horizontal row via connection nodes 320.

A single VccQ packaging ball 310 or a single Vpp packaging ball 310 or a single VssQ packaging ball 310 can be connected to one or more chips 330. For example, the single Vpp packaging ball 310 in FIG. 3 is connected to all chips 330. The rest can be inferred accordingly. Because during normal operation of the system, large currents are usually not needed from the power sources VccQ, VssQ, and Vpp, there is generally no concern about excessively high peak currents.

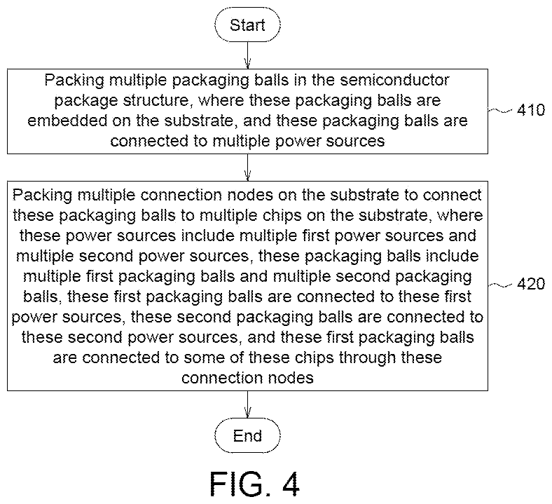

FIG. 4 shows a method for reducing the peak current of a semiconductor package structure according to the third embodiment of the present invention, including: (410) packing multiple packaging balls in the semiconductor package structure, where these packaging balls are embedded on the substrate, and these packaging balls are connected to multiple power sources; (420) packing multiple connection nodes on the substrate to connect these packaging balls to multiple chips on the substrate, where these power sources include multiple first power sources and multiple second power sources, these packaging balls include multiple first packaging balls and multiple second packaging balls, these first packaging balls are connected to these first power sources, these second packaging balls are connected to these second power sources, and these first packaging balls are connected to some of these chips through these connection nodes.

In the above method, each of these first packaging balls is connected to a single chip through one of these connection nodes.

In the above method, each of these first packaging balls is connected to two chips through one of these connection nodes.

In the above method, these first power sources include an operating voltage and a ground voltage.

In the above method, each of these second packaging balls is connected to all these chips through one of these connection nodes.

Furthermore, the fourth embodiment of the present invention discloses a semiconductor device, including: multiple chips; a substrate on which these chips are packed; multiple packaging balls embedded on the substrate and connected to multiple power sources; and multiple connection nodes packed on the substrate to connect these packaging balls to these chips. These power sources include multiple first power sources and multiple second power sources. These packaging balls include multiple first packaging balls and multiple second packaging balls. These first packaging balls are connected to these first power sources, and these second packaging balls are connected to these second power sources. These first packaging balls are connected to some of these chips through these connection nodes.

In the above semiconductor device, each of these first packaging balls is connected to a single chip through one of these connection nodes.

In the above semiconductor device, each of these first packaging balls is connected to two chips through one of these connection nodes.

In the above semiconductor device, these first power sources include an operating voltage and a ground voltage.

In the above semiconductor device, each of these second packaging balls is connected to all these chips through one of these connection nodes.

As can be seen from the above, in several embodiments of the present invention, in the packaging structure, the reduction of peak current can be achieved, thereby reducing the risk of system collapse due to excessive current. Since peak current is the maximum current flowing through the circuit during transient conditions, reducing peak current helps maintain the stability and reliability of the system. Vcc (positive power source) and Vss (negative power source) are power sources in the circuit, and by minimizing the number of chips connected to Vcc power source and Vss power source (via Vcc packaging balls and Vss packaging balls), the load on the Vcc power and the Vss power source can be reduced, reducing current fluctuations.

For example, but not limited to, by reducing the number of chips connected to a single Vcc packaging ball and a single Vss packaging ball, and by preventing Vcc packaging balls and Vss packaging balls connecting to all chips, the design goal is to ensure that each Vcc packaging ball and each Vss packaging ball carries the load of one chip or two chips or a few chips without loading all the chips, effectively reducing peak current, and thus reducing current fluctuations in the system.

In other words, several embodiments of the present invention can reduce the risk of system collapse by distributing the load to multiple Vcc packaging balls and multiple Vss packaging balls, helping balance the current distribution in the system. This can reduce the risk of system collapse due to excessively high peak currents.

As for the appropriate number of chips connected to a single Vcc packaging ball and a single Vss packaging ball, it depends on the number of Vcc packaging balls and Vss packaging balls in the packaging structure, the upper limit of peak current, and the number of chips, etc. Different designs of packaging structures may require different numbers of connections to ensure stable operation of the system under various working conditions.

While this document may describe many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination in some cases can be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

What is claimed is:

1. A multi-chip packaging structure comprising:
a substrate having a plurality of chips packed on the substrate;
a plurality of packaging balls embedded on the substrate, connected to a plurality of power sources; and
a plurality of connection nodes packed on the substrate to connect the packaging balls to the chips,
wherein
the power sources include a plurality of first power sources and a plurality of second power sources;
the packaging balls include a plurality of first packaging balls and a plurality of second packaging balls, with the first packaging balls connected to the first power sources and the second packaging balls connected to the second power sources; and
the first packaging balls are connected to a part of the chips through the connection nodes.

2. The multi-chip packaging structure of claim 1, wherein each of the first packaging balls is connected to a single chip of the chips through one of the connection nodes.

3. The multi-chip packaging structure of claim 1, wherein each of the first packaging balls is connected to two chips of the chips through one of the connection nodes.

4. The multi-chip packaging structure of claim 1, wherein the first power sources include an operating voltage and a ground voltage.

5. The multi-chip packaging structure of claim 1, wherein each of the second packaging balls is connected to all the chips through one of the connection nodes.

6. A method for reducing a peak current of a semiconductor packaging structure, the method comprising:
packing a plurality of packaging balls in the semiconductor packaging structure, where the packaging balls are embedded on a substrate and are connected to a plurality of power sources;
packing a plurality of connection nodes on the substrate to connect the packaging balls to a plurality of chips on the substrate;
wherein:
the power sources include a plurality of first power sources and a plurality of second power sources;
the packaging balls include a plurality of first packaging balls and a plurality of second packaging balls, with the first packaging balls connected to the first power sources and the second packaging balls connected to the second power sources; and
the first packaging balls are connected to a part of the chips through the connection nodes.

7. The method of claim 6, wherein each of the first packaging balls is connected to a single chip of the chips through one of the connection nodes.

8. The method of claim 6, wherein each of the first packaging balls is connected to two chips of the chips through one of the connection nodes.

9. The method of claim 6, wherein the first power sources include an operating voltage and a ground voltage.

10. The method of claim 6, wherein each of the second packaging balls is connected to all the chips through one of the connection nodes.

11. A semiconductor device comprising:
a plurality of chips;
a substrate having the chips packed on the substrate;
a plurality of packaging balls embedded on the substrate, connected to a plurality of power sources; and
a plurality of connection nodes packed on the substrate to connect the packaging balls to the chips,
wherein:
the power sources include a plurality of first power sources and a plurality of second power sources;
the packaging balls include a plurality of first packaging balls and a plurality of second packaging balls, with the first packaging balls connected to the first power sources and the second packaging balls connected to the second power sources; and
the first packaging balls are connected to a part of the chips through the connection nodes.

12. The semiconductor device of claim 11, wherein each of the first packaging balls is connected to a single chip of the chips through one of the connection nodes.

13. The semiconductor device of claim 11, wherein each of the first packaging balls is connected to two chips of the chips through one of the connection nodes.

14. The semiconductor device of claim 11, wherein the first power sources include an operating voltage and a ground voltage.

15. The semiconductor device of claim 11, wherein each of the second packaging balls is connected to all the chips through one of the connection nodes.
